(19) United States
(12) Patent Application Publication
(10) Pub. No.: US 2026/0348663 A1
(43) Pub. Date: Nov. 5, 2026

(54) WATER-COOLED HEAT SHIELD FOR SINGLE CRYSTAL FURNANCE

(71) Applicant: Zhongshan Huichuang Precision Technology Co., Ltd., Zhongshan (CN)

(72) Inventor: Longqiang LIN, Zhongshan (CN)

(21) Appl. No.: 19/707,244

(22) Filed: Jun. 13, 2026

(30) Foreign Application Priority Data
Mar. 25, 2026 (CN) 202620378775.0

(51) Int. Cl. F27D 5/00; C30B 15/20; F27D 9/00; F27D 21/02

(52) U.S. Cl. CPC F27D 5/0062; F27D 21/02; C30B 15/20; F27D 2009/0018

(57) ABSTRACT

A water-cooled heat shield for a single crystal furnace is published, wherein a viewing section arranged on a main housing penetrates the main housing and communicates with a cavity. Operators can directly observe the single crystal growth state inside the cavity from outside through the viewing section, and monitor diameter variation and surface quality of the single crystal in real time which facilitates timely adjustment of process parameters, and improves the stability of single crystal growth and the product yield.

### RELATED APPLICATIONS

The present patent document claims the benefit of priority to Patent Application No. 202620378775.0, filed Mar. 25, 2026, and entitled “WATER-COOLED HEAT SHIELD FOR SINGLE CRYSTAL FURNACE,” the entire contents of each of which are incorporated herein by reference.

### BACKGROUND

### 1. Technical Field

The present invention relates to the technical field of auxiliary equipment for single crystal furnaces, and in particular to a water-cooled heat shield for a single crystal furnace.

### 2. Background Information

A single crystal furnace is the core equipment for manufacturing monocrystalline silicon rods. It mainly adopts the Czochralski process to grow monocrystalline silicon rods from molten high-purity polysilicon via liquid-phase crystallization, and is widely used in the photovoltaic and semiconductor industries.

As a key component of the thermal field in a single crystal furnace, the water-cooled heat shield can effectively block thermal radiation from the melt and optimize the axial temperature gradient, so as to improve the growth stability and crystal quality of monocrystalline silicon rods.

Existing water-cooled heat shields are generally designed as straight cylinders to adapt to the growth of large-size single crystals and provide a stable thermal field environment. However, such cylindrical shape blocks the viewing range inside the furnace. Operators cannot directly observe the growth state of single crystals inside the shield, making it impossible to monitor crystal diameter changes and surface quality in real time, thereby further impairing crystal quality and production yield.

### BRIEF SUMMARY

In order to solve the above-mentioned problem that existing water-cooled heat shields is generally designed as straight cylindrical shape, which prevents operators from directly observing the single crystal growth state inside the shield and conducting real-time monitoring of crystal diameter variation and surface quality, the technical solution adopted by the present invention is as follows:

A water-cooled heat shield, comprising a main housing, wherein a cavity extending in an axial direction is enclosed inside the main housing for a single crystal to pass through; a viewing section arranged on the main housing penetrates the main housing and communicates with the cavity.

Further, the viewing section is a viewing port disposed on a side wall of the main housing.

Further, the main housing comprises an upper heat shield housing and a lower heat shield housing arranged under the upper heat shield housing, wherein the viewing port is located on an end of the upper heat shield housing close to the lower heat shield housing.

Further, the cavity comprises an upper cavity disposed in the upper heat shield housing and a lower cavity disposed in the lower heat shield housing, wherein the upper cavity is communicated with the lower cavity.

Further, the viewing port is integrally formed on the side wall of the main housing.

Further, a cross section of the viewing port is rectangular.

Further, an axial height H1 of the viewing port is ¼ to ⅓ of an axial height H2 of the upper heat shield housing 1.

Further, a length L1 of the viewing port perpendicular to a radial direction is ⅙ to ¼ of a length L2 of the upper heat shield housing perpendicular to the radial direction.

Further, corners of the viewing port are configured as arc transition structures;

Further, the viewing port is provided in a plurality, and the plurality of the viewing port are disposed at intervals along a circumferential direction of the main housing.

Further, the water-cooled heat shield further comprises a liquid inlet pipe and a liquid outlet pipe, wherein the main housing is in communication with the liquid inlet pipe and liquid outlet pipe respectively.

Further, an upper heat exchange passage is arranged between inner and outer side walls of the upper heat shield housing, a lower heat exchange passage is arranged between the inner and outer side walls of the lower heat shield housing, and the upper heat exchange passage is communicated with the lower heat exchange passage.

Further, a delivery pipe is arranged between the upper heat shield housing and the lower heat shield housing for communicating the upper heat exchange passage and the lower heat exchange passage.

Further, a cross section of the upper heat exchange passage is adapted to that of the upper heat shield housing, and a cross section of the lower heat exchange passage is adapted to that of the lower heat shield housing.

Further, the liquid inlet pipe is in communication with the lower heat exchange passage, and the liquid outlet pipe is in communication with the upper heat exchange passage.

Beneficial effects of the present invention are as follows:

In the present invention, the viewing section arranged on the main housing penetrates the main housing and communicates with the cavity. Operators can directly observe the single crystal growth state inside the cavity from outside through the viewing section, and monitor diameter variation and surface quality of the single crystal in real time which facilitates timely adjustment of process parameters, and improves the stability of single crystal growth and the product yield. This effectively solves the existing problem that conventional water-cooled heat shields are generally of straight cylindrical shape which prevents operators from directly observing the growth of single crystals inside the shield, and thus fails to monitor the crystal diameter variation and surface quality in real time.

### BRIEF DESCRIPTION OF THE DRAWINGS

FIG. 1 is a first structural schematic view of the water-cooled heat shield according to the present invention;

FIG. 2 is a first structural schematic view of the upper heat shield housing according to the present invention;

FIG. 3 is a sectional view along line A-A of FIG. 2;

FIG. 4 is a second structural schematic view of the upper shield housing according to the present invention;

FIG. 5 is a second structural schematic view of the water-cooled heat shield according to the present invention;

FIG. 6 is a sectional view along line B-B of FIG. 5.

### DETAILED DESCRIPTION OF THE DRAWINGS AND THE PRESENTLY PREFERRED EMBODIMENTS

The embodiments of the present invention are further illustrated hereafter in combination with the accompany drawings.

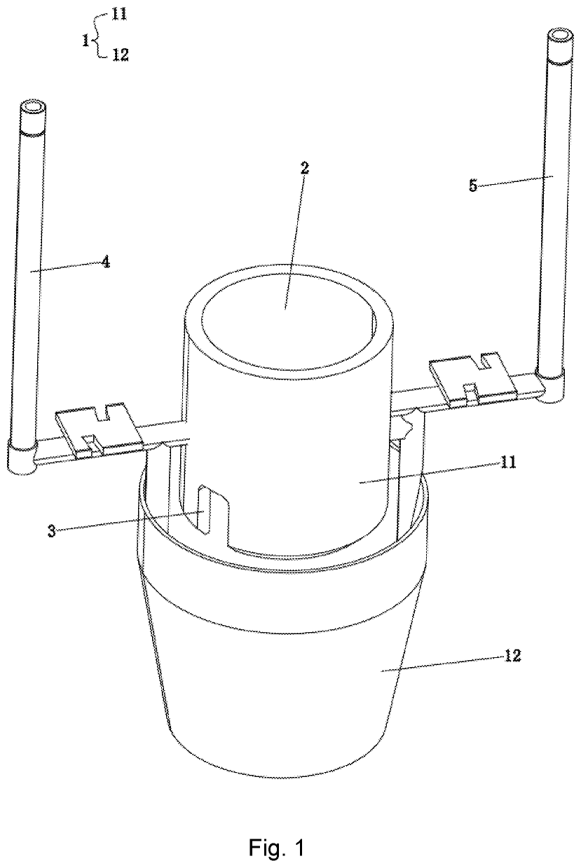

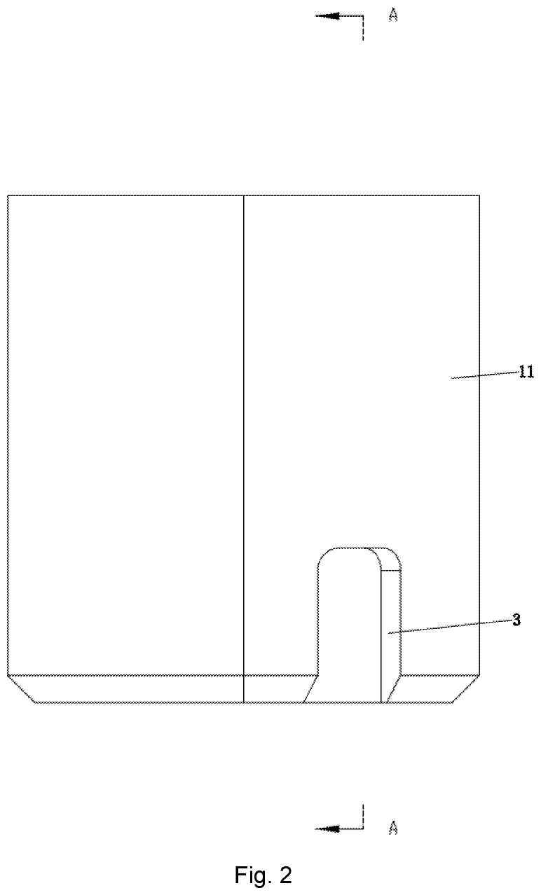

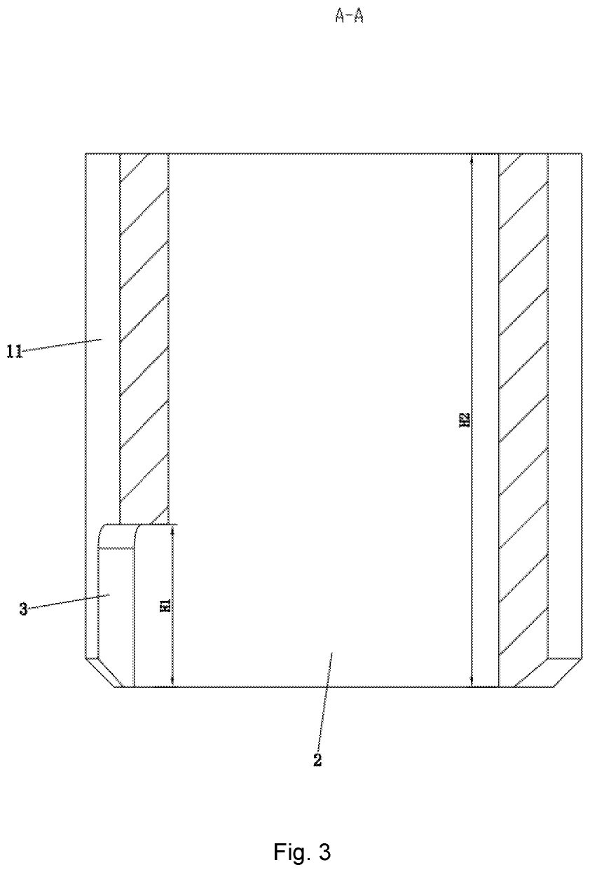

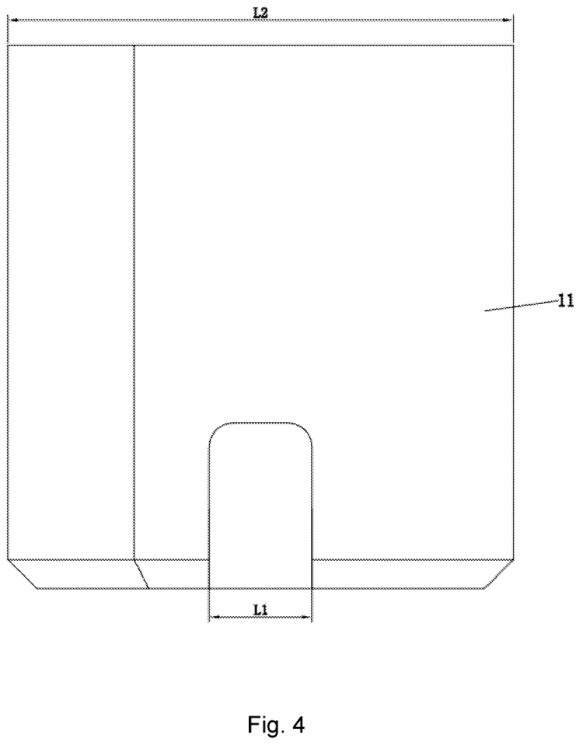

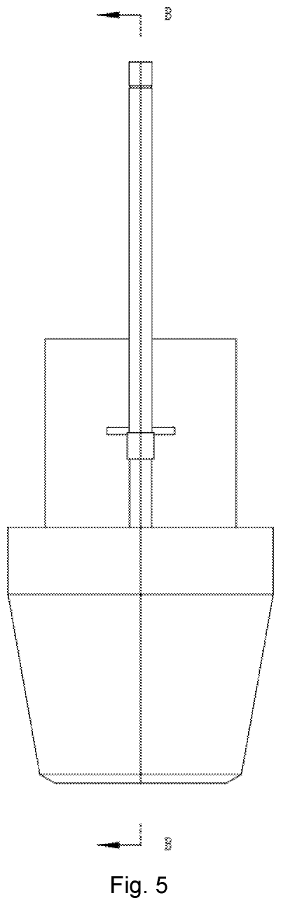

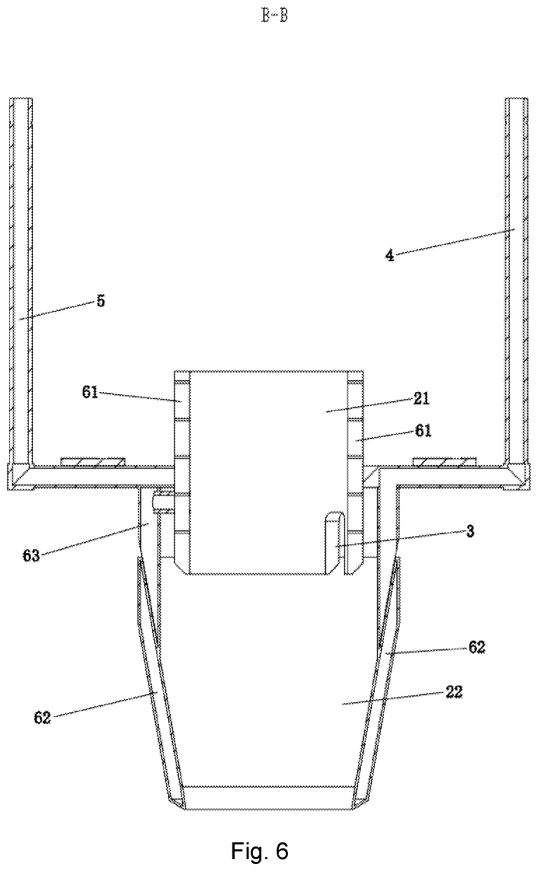

A water-cooled heat shield for single crystal furnace as shown in FIGS. 1 to 6, comprising a main housing 1, wherein a cavity 2 extending in an axial direction is enclosed inside the main housing 1, and the cavity 2 is configured for a single crystal to pass through; a viewing section 3 arranged on the main housing 1 penetrates the main housing 1 and communicates with the cavity 2.

In the present invention, the viewing section 3 arranged on the main housing penetrates the main housing and communicates with the cavity. Operators can directly observe the single crystal growth state inside the cavity from outside through the viewing section, and monitor diameter variation and surface quality of the single crystal in real time which facilitates timely adjustment of process parameters, and improves the stability of single crystal growth and the product yield. This effectively solves the existing problem that conventional water-cooled heat shields are generally of straight cylindrical shape which prevents operators from directly observing the growth of single crystals inside the shield, and thus fails to monitor the crystal diameter variation and surface quality in real time.

Alternatively, the viewing section 3 comprises a viewing window and a transparent heat insulator. A through mounting hole is disposed on the main housing 1, and the transparent heat insulator is sealingly mounted inside the mounting hole. The transparent heat insulator adopts high-temperature resistant transparent materials such as high-temperature resistant quartz glass or sapphire glass, enabling real-time observation of single crystal growth and preventing internal heat of the furnace from escaping.

Preferably, the viewing section 3 is a viewing port 3 directly arranged on the main housing 1, wherein the viewing port 3 penetrates the main housing 1 and communicates the cavity 2. The viewing port 3 may be circular, rectangular or polygonal, with an edge thereof and the main housing 1 formed integrally. This structure requires no additional assembly parts, featuring low processing cost and no connecting gaps.

As shown in FIGS. 1 to 6, the viewing section is a viewing port 3 disposed on a side wall of the main housing 1;

Specifically, the viewing section is a viewing port 3 disposed on a side wall of the main housing 1, which creates a direct line of sight between the inside and outside of the main housing 1, enabling operators or detection devices to directly observe the single crystal growth inside the cavity 2 through the viewing port 3, facilitating the monitoring of the crystal diameter variation and surface quality in real time, thereby timely detecting abnormal growth and promptly adjusting process parameters to reduce growth defects. Furthermore, the opening arranged on the side wall is a simple and reliable structure, preserving the overall structural strength and thermal insulation performance of the main housing 1 to the greatest extent, while enabling observation, and making it possible to satisfy both the observation requirement and the shielding protection.

As shown in FIGS. 1 to 6, the main housing 1 comprises an upper heat shield housing 11 and a lower heat shield housing 12 arranged under the upper heat shield housing 11, wherein the viewing port 3 is located on an end of the upper heat shield housing 11 close to the lower heat shield housing 12;

Further, the main housing 1 is divided into the upper heat shield housing 11 and the lower heat shield housing 12, and the viewing port 3 is disposed on an end of the upper heat shield housing 11 close to the lower heat shield housing 12. Such design not only ensures the overall structural stability as well as reliable heat insulation and heat dissipation of the water-cooled heat shield, but also aligns the viewing port 3 precisely with the key area for single crystal growth, enabling operators to observe the single crystal growth interface, diameter variation and surface state intuitively and clearly.

Further, the cavity 2 comprises an upper cavity disposed in the upper heat shield housing 11 and a lower cavity disposed in the lower heat shield housing 12, wherein the upper cavity is communicated with the lower cavity. The lower cavity serves as the main space, which is adjacent to the single crystal growth interface and high-temperature melt zone, performing primary heat exchange and thermal insulation to rapidly absorb heat and achieve stable temperature control. The upper cavity then carries out secondary cooling for the formed crystal, further optimizing the temperature gradient, improving heat exchange efficiency and cooling uniformity and thereby effectively increasing the crystal pulling speed and enhances the quality of single crystal growth.

As shown in FIGS. 1 to 6, the viewing port 3 is integrally formed on a side wall of the main housing 1;

Further, the viewing port 3 is integrally formed on the side wall of the main housing 1, improving the structural integrity and connection strength between the viewing port 3 and the main housing 1, avoiding sealing risks and structural defects caused by splicing or assembly structures. It also simplifies machining and assembly procedures, and ensures the sealing performance and thermal insulation stability of the side wall of the water-cooled heat shield. While enabling internal observation, the overall structural reliability is guaranteed and the service life of the equipment is prolonged.

As shown in FIGS. 1 to 6, the cavity 2 comprises an upper cavity 21 disposed in the upper heat shield housing 11 and a lower cavity 22 disposed in the lower heat shield housing 12, wherein the upper cavity 21 is communicated with the lower cavity 22.

As shown in FIGS. 1 to 6, a cross section of the viewing port 3 is rectangular.

Further, compared with a circular structure, the viewing port 3 with a rectangular cross section features an adjustable aspect ratio to meet observation needs, providing a larger effective light transmission area under the same space occupation, broadening the axial and circumferential viewing field. It facilitates operators to fully monitor diameter changes and surface edge conditions of the growing single crystal, thereby minimizing observation blind spots.

As shown in FIGS. 1 to 6, an axial height H1 of the viewing port 3 is ¼ to ⅓ of an axial height H2 of the upper heat shield housing 11;

Further, the axial height H1 of the viewing port 3 is configured to be ¼ to ⅓ of the axial height H2 of the upper heat shield housing 11, which not only provides a sufficient viewing area for clear and continuous observation of single crystal growth, but also prevents excessive openings from impairing the structural strength and thermal insulation performance of the upper heat shield housing 11. It balances viewing range, structural stability and thermal field uniformity, and ensures stable and reliable single crystal growth.

Alternatively, the axial height H1 of the viewing port 3 is configured to be ¼ of the axial height H2 of the upper heat shield housing 11. With such proportion, an opening size of the viewing port 3 is moderate, which effectively maintains the structural strength and thermal insulation performance of the upper heat shield housing 11, reduces disturbance to the thermal field inside the furnace, meets basic observation requirements and improves overall structural stability.

Alternatively, the axial height H1 of the viewing port 3 is configured to be ⅓ of the axial height H2 of the upper heat shield housing 11, which broadens the viewing field for comprehensive and continuous monitoring of the single crystal growth interface and crystal state while ensuring the basic stability of the structure and thermal field of the upper heat shield housing 11, thereby improving the monitoring range and visibility.

As shown in FIGS. 1 to 6, a length L1 of the viewing port 3 perpendicular to the radial direction is ⅙ to ¼ of a length L2 of the upper heat shield housing 11 perpendicular to the radial direction.

Specifically, the length perpendicular to the radial direction refers to the horizontal length of the cross section of the upper heat shield housing 11. Further, the length L1 of the viewing port 3 perpendicular to the radial direction is configured to be ⅙ to ¼ of the corresponding horizontal length L2 of the upper heat shield housing 11, which not only ensures a sufficient circumferential viewing range for clearly viewing the growth state of crystal, but also prevents an excessively wide opening from reducing the structural strength, thermal insulation and sealing performance of the housing, thereby achieving a good balance among viewing range, structural strength and thermal field stability.

Alternatively, the length L1 of the viewing port 3 perpendicular to the radial direction is configured to be ⅙ of the corresponding horizontal length L2 of the upper heat shield housing 11. With such a dimensional proportion, the opening is relatively small, which maximizes the structural strength, thermal insulation and sealing performance of the upper heat shield housing 11 and exerts little influence on the thermal field distribution inside the furnace, making it suitable for single crystal growth processes with strict requirements on thermal field stability.

Alternatively, the length L1 of the viewing port 3 perpendicular to the radial direction is configured to be ¼ of the corresponding horizontal length L2 of the upper heat shield housing 11, which broadens the circumferential viewing field for comprehensive observation of the crystal growth interface and diameter changes while ensuring the basic stability of the structure and thermal field of the upper heat shield housing 11, thereby improving the monitoring visibility and comprehensiveness.

As shown in FIGS. 1 to 6, corners of the viewing port 3 are configured as arc transition structures;

Further, the arc transition structures disposed on the corner of the viewing port 3 effectively eliminate stress concentration in sharp corners, improve the structural strength and deformation resistance of the upper heat shield housing 11, and reduce the risk of cracking under high temperature and heat exchange conditions. In addition, the arc transition structure smoothens edges of the viewing port 3, facilitates processing and forming, avoids interference caused by sharp corners during assembly and operation, and further enhances the reliability and service life of the water-cooled heat shield.

As shown in FIGS. 1 to 6, the viewing port 3 is provided in a plurality, and the plurality of the viewing port 3 are disposed at intervals along a circumferential direction of the main housing 1;

Further, the plurality of the viewing port 3, disposed at intervals along a circumferential direction of the main housing 1, allow observation of the single crystal growth in multiple directions, effectively reduce observation blind spots, achieve comprehensive monitoring of crystal diameter, surface quality and growth interface, and facilitate operators to acquire real-time and accurate information on the crystal pulling process. Meanwhile, the distributed opening can reduce the adverse impact on the overall structural strength and thermal field uniformity of the main housing 1, which helps ensure stable and reliable single crystal growth.

As shown in FIGS. 1 to 6, the water-cooled heat shield further comprises a liquid inlet pipe 4 and a liquid outlet pipe 5, wherein the main housing 1 is in communication with the liquid inlet pipe 4 and liquid outlet pipe 5 respectively;

Further, the liquid inlet pipe 4 and the liquid outlet pipe 5 that are in communication with the main housing 1, forms a coolant circulation channel to form inside the housing for active high-efficiency heat exchange. Coolant enters internal flow passages of the main housing 1 from the liquid inlet pipe 4, quickly carries away radiant heat and latent heat of crystallization in the single crystal growth process, and exits through the liquid outlet pipe 5, which stabilizes the temperature gradient of the thermal field, prevents components from being damaged by high temperature, prolongs equipment service life, and greatly enhances single crystal growth efficiency and crystal quality.

Specifically, an upper heat exchange passage 61 is arranged between inner and outer side walls of the upper heat shield housing 11, wherein a cross section of the upper heat exchange passage 61 is adapted to that of the upper heat shield housing 11. A lower heat exchange passage 62 is arranged between the inner and outer side walls of the lower heat shield housing 12, wherein a cross section of the lower heat exchange passage 62 is adapted to that of the lower heat shield housing 12. A delivery pipe 63 is arranged between the upper heat shield housing 11 and the lower heat shield housing 12 for communicating the upper heat exchange passage 61 and the lower heat exchange passage 62. The liquid inlet pipe 4 is in communication with the lower heat exchange passage 62, and the liquid outlet pipe 5 is in communication with the upper heat exchange passage 61. Coolant first flows into the lower heat exchange passage 62 through the liquid inlet pipe 4 to perform primary heat exchange and cooling on the high-temperature area adjacent to the melt. The heated coolant in the lower heat exchange passage 62 then passes through the delivery pipe 63 into the upper heat exchange passage 61 for secondary cooling of the crystal, and is finally discharged to the outside via the liquid outlet pipe 5. Such design forms a complete continuous multi-stage circulating cooling circuit, which helps improve heat exchange efficiency and cooling uniformity.

1. A water-cooled heat shield, comprising a main housing, wherein a cavity extending in an axial direction is enclosed inside the main housing for a single crystal to pass through; a viewing section arranged on the main housing penetrates the main housing and communicates with the cavity.

2. The water-cooled heat shield according to claim 1, wherein the viewing section is a viewing port disposed on a side wall of the main housing.

3. The water-cooled heat shield according to claim 2, wherein the main housing comprises an upper heat shield housing and a lower heat shield housing arranged under the upper heat shield housing; the viewing port is located on an end of the upper heat shield housing close to the lower heat shield housing.

4. The water-cooled heat shield according to claim 3, wherein the cavity comprises an upper cavity disposed in the upper heat shield housing and a lower cavity disposed in the lower heat shield housing, wherein the upper cavity is communicated with the lower cavity.

5. The water-cooled heat shield according to claim 2, wherein the viewing port is integrally formed on the side wall of the main housing.

6. The water-cooled heat shield according to claim 3, wherein a cross section of the viewing port is rectangular.

7. The water-cooled heat shield according to claim 6, wherein an axial height H1 of the viewing port is ¼ to ⅓ of an axial height H2 of the upper heat shield housing.

8. The water-cooled heat shield according to claim 6, wherein a length L1 of the viewing port perpendicular to a radial direction is ⅙ to ¼ of a length L2 of the upper heat shield housing perpendicular to the radial direction.

9. The water-cooled heat shield according to claim 6, wherein corners of the viewing port are configured as arc transition structures.

10. The water-cooled heat shield according to claim 2, wherein the viewing port is provided in a plurality, and the plurality of the viewing port are disposed at intervals along a circumferential direction of the main housing.

11. The water-cooled heat shield according to claim 1, wherein the water-cooled heat shield further comprises a liquid inlet pipe and a liquid outlet pipe; the main housing is in communication with the liquid inlet pipe and liquid outlet pipe respectively.

12. The water-cooled heat shield according to claim 11, wherein an upper heat exchange passage is arranged between inner and outer side walls of the upper heat shield housing, a lower heat exchange passage is arranged between the inner and outer side walls of the lower heat shield housing, and the upper heat exchange passage is communicated with the lower heat exchange passage.

13. The water-cooled heat shield according to claim 12, wherein a delivery pipe is arranged between the upper heat shield housing and the lower heat shield housing for communicating the upper heat exchange passage and the lower heat exchange passage.

14. The water-cooled heat shield according to claim 12, wherein a cross section of the upper heat exchange passage is adapted to that of the upper heat shield housing, and a cross section of the lower heat exchange passage is adapted to that of the lower heat shield housing.

15. The water-cooled heat shield according to claim 12, wherein the liquid inlet pipe is in communication with the lower heat exchange passage, and the liquid outlet pipe is in communication with the upper heat exchange passage.
